(19) United States
(12) Patent Application Publication
(10) Pub. No.: US 2026/0150578 A1
(43) Pub. Date: May 28, 2026

(54) HIGH ASPECT RATIO BERYLLIUM OXIDE NANOROD AND METHOD FOR MANUFACTURING SAME

(71) Applicant: INDUSTRY-ACADEMIC COOPERATION FOUNDATION, YONSEI UNIVERSITY, Seoul (KR)

(72) Inventors: Jung Woo OH, Incheon (KR); Yoon Seo JANG, Incheon (KR); Ji Won KIM, Incheon (KR); Ji Hyeon PARK, Incheon (KR)

(21) Appl. No.: 19/402,688

(22) Filed: Nov. 26, 2025

(30) Foreign Application Priority Data
Nov. 28, 2024 (KR) 10-2024-0173699
Oct. 29, 2025 (KR) 10-2025-0158682

(51) Int. Cl. H10N 30/076; H10N 30/093; H10N 30/853

(52) U.S. Cl. CPC H10N 30/076; H10N 30/093; H10N 30/8536

(57) ABSTRACT

An embodiment relates to a high aspect ratio beryllium oxide nanorod and a method for manufacturing the same. The method for manufacturing a high aspect ratio beryllium oxide nanorod according to an embodiment of the disclosure utilizes an atomic layer deposition (ALD) process. Furthermore, the high aspect ratio beryllium oxide nanorod manufactured using the method according to the embodiment may induce large deformation with a small force due to its high aspect ratio, and may be used as a high-sensitivity, high-energy piezoelectric element.

### CROSS REFERENCE TO RELATED APPLICATION

The present application claims priority to Korean Patent Application 10-2024-0173699, filed Nov. 28, 2024, and Korean Patent Application 10-2025-0158682, filed Oct. 29, 2025, in the Korean Intellectual Property Office, the entire contents of which are incorporated here for all purposes by this reference.

### BACKGROUND

The disclosure relates to a high aspect ratio beryllium oxide nanorod, and a technology for manufacturing a high aspect ratio beryllium oxide nanorod using an aluminum oxide (AAO) template.

Previous research on beryllium compound manufacturing has been limited to the synthesis of bulk or film-form beryllium oxide.

In particular, the synthesis of arrays of beryllium oxide (BeO) nanorods has not been reported; nanorods can be synthesized using methods such as CVD, sputter, and evaporator, whereas beryllium's inherent toxicity makes these methods such as CVD, sputter, and evaporation infeasible.

Therefore, many challenges remain for the manufacturing of beryllium oxide nanorods.

### RELATED ART DOCUMENT

### Patent Document

Republic of Korea Patent Publication No. 10-2023-0118803

### SUMMARY

An aspect of the disclosure is to provide a high aspect ratio beryllium oxide nanorod having excellent piezoelectric properties and electrical performance and a method for manufacturing the same.

The aspect of the disclosure is not limited to that mentioned above, and other aspects not mentioned will be clearly understood by those skilled in the art from the description below.

An embodiment of the disclosure provides a beryllium oxide nanorod.

A beryllium oxide nanorod according to an embodiment of the disclosure is manufactured by performing a method for manufacturing a high aspect ratio beryllium oxide nanorod.

At this time, the beryllium oxide nanorod may have a width of 10 nm to 400 nm and a length of 10 μm to 100 μm.

Another embodiment of the disclosure provides a method for manufacturing a high aspect ratio beryllium oxide nanorod.

A method for manufacturing a high aspect ratio beryllium oxide nanorod according to an embodiment of the disclosure may include: growing one dimensional nanorod-structured beryllium oxide within a pore of a Anodic aluminum oxide (AAO) template using an atomic layer deposition (ALD) process; removing the anodic aluminum oxide (AAO) template, in which the one-dimensional nanorod-structured beryllium oxide is formed in the pore therein, by chemically dissolving the anodic aluminum oxide (AAO) template; and obtaining a beryllium oxide nanorod by washing the beryllium oxide removed from the anodic aluminum oxide template by using water and ethanol, wherein the beryllium oxide nanorod has a crystalline wurtzite structure.

In addition, according to an embodiment of the disclosure, in the growing of the one-dimensional nanorod-structured beryllium oxide, the diameter of the pore of the anodic aluminum oxide (AAO) template may be 10 nm to 400 nm.

In addition, according to an embodiment of the disclosure, in the growing of the one-dimensional nanorod-structured beryllium oxide, the atomic layer deposition (ALD) process may form beryllium oxide by reacting beryllium diethyl (Be(C₂H₅)₂) as a beryllium precursor with oxygen plasma.

In addition, according to an embodiment of the disclosure, in the atomic layer deposition (ALD) process, one cycle may be set to have a beryllium precursor injection time of 5 seconds or more and a purge time of 30 seconds or more after the reaction of the beryllium precursor and oxygen plasma.

In addition, according to an embodiment of the disclosure, in the removing of the anodic aluminum oxide (AAO) template, the chemically dissolving may be dissolving by introducing, into a sodium hydroxide aqueous solution, a anodic aluminum oxide (AAO) template in which one-dimensional nanorod-structured beryllium oxide is formed in a pore therein.

At this time, phosphoric acid and hydrochloric acid may be used in addition to sodium hydroxide as an etchant to remove anodic aluminum oxide (AAO), and if it is an etchant that does not damage beryllium oxide (BeO), it can be used without restriction.

In addition, according to an embodiment of the disclosure, in the obtaining of the beryllium oxide nanorod, the beryllium oxide nanorod may have a width of 10 nm to 400 nm and a length of 10 μm to 100 μm.

In addition, the method may further include, between the growing of the one-dimensional nanorod-structured beryllium oxide and the removing of the anodic aluminum oxide (AAO) template, physically removing a beryllium oxide thin film deposited on the aluminum oxide (AAO) template by using sandpaper.

In addition, the method may further include: before the growing of the one-dimensional nanorod-structured beryllium oxide, depositing a metal thin film on the aluminum oxide (AAO) template; and after the growing of the one-dimensional nanorod-structured beryllium oxide, chemically etching the metal thin film, so as to chemically remove a beryllium oxide film deposited on the aluminum oxide (AAO) template.

Another embodiment of the disclosure provides a piezoelectric element.

A piezoelectric element according to an embodiment of the disclosure may include a beryllium oxide nanorod manufactured by performing a method for manufacturing a high aspect ratio beryllium oxide nanorod.

A method for manufacturing a high aspect ratio beryllium oxide nanorod according to an embodiment of the disclosure utilizes an atomic layer deposition (ALD) process.

Furthermore, chemical dissolution allows for easy removal of the AAO template.

Furthermore, quantitative control of the length and width of the beryllium oxide nanorod is possible by adjusting the diameter of a pore of the AAO template.

Furthermore, the high aspect ratio beryllium oxide nanorod manufactured using the method according to an embodiment of the disclosure allows the nanorod to undergo relatively large deformation under a given external force due to its high aspect ratio, and can be used as a high-sensitivity, high-energy piezoelectric element.

The effects of the disclosure are not limited to the effects described above, and should be understood to include all effects that are inferable from the configuration of the disclosure described in the detailed description or claims of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating a method for manufacturing a high aspect ratio beryllium oxide nanorod array; The same method may also be applied to synthesize a single nanorod depending on the processing condition (e.g. sand paper)

FIG. 2 is a schematic diagram illustrating a crystalline wurtzite structure of a high aspect ratio beryllium oxide nanorod array;

FIG. 3 is a schematic diagram illustrating a method for manufacturing a high aspect ratio beryllium oxide nanorod array;

FIG. 4 is a SEM image showing the top and bottom of a high aspect ratio beryllium oxide nanorod;

FIG. 5 is a SEM image of a high aspect ratio beryllium oxide nanorod;

FIG. 6 is a SEM image showing a high aspect ratio beryllium oxide nanorod;

FIG. 7 is an energy-dispersive spectroscopy (SEM-EDS) elemental mapping image illustrating the results of component analysis of a high aspect ratio beryllium oxide nanorod; (Elemental mapping from the SEM image in FIG. 6)

FIG. 8 is an energy-dispersive spectroscopy (SEM-EDS) elemental mapping image illustrating the results of component analysis of a high aspect ratio beryllium oxide nanorod; (Elemental mapping from the SEM image in (b) of FIG. 5)

FIG. 9 is a TEM image of a high aspect ratio beryllium oxide nanorod;

FIG. 10 is a TEM image of a high aspect ratio beryllium oxide nanorod;

FIG. 11 is a TEM image of a high aspect ratio beryllium oxide nanorod;

FIG. 12 is a SAD diffraction pattern of a high aspect ratio beryllium oxide nanorod;

FIG. 13 is a diagram showing the piezoelectric properties of a high aspect ratio beryllium oxide nanorod; and

FIG. 14 is a diagram showing the improved performance of high aspect ratio beryllium oxide nanorod piezoelectric device.

### DETAILED DESCRIPTION

Hereinafter, the disclosure will be described with reference to the accompanying drawings. However, the disclosure may be implemented in various different forms and therefore is not limited to the embodiments described herein. In addition, in order to clearly describe the disclosure in the drawings, parts that are not related to the description are omitted, and similar parts are given similar drawing reference numerals throughout the specification.

In the entire specification, when a part is said to be “connected (linked, contacted, coupled)” to another part, this includes not only the case where it is “directly connected” but also the case where it is “indirectly connected” with another member in between. In addition, when a part is said to “include” a component, this does not mean that it excludes other components, unless otherwise specifically stated, but rather that it may include other components.

The terms used in this specification are used only to describe specific embodiments and are not intended to limit the disclosure. The singular expression includes the plural expression unless the context clearly indicates otherwise. In this specification, the terms “include” or “have” are intended to specify the presence of a feature, number, step, operation, component, part, or combination thereof described in the specification, but should be understood as not excluding in advance the possibility of the presence or addition of one or more other features, numbers, steps, operations, components, parts, or combinations thereof.

Hereinafter, embodiments of the disclosure will be described in detail with reference to the accompanying drawings. For reference, the drawings may be exaggerated to illustrate some features of the disclosure. In this case, it is preferable to interpret them in light of the full scope of the present specification.

### A Method for Manufacturing a High Aspect Ratio Beryllium Oxide Nanorod According to an Embodiment of the Disclosure Will be Described

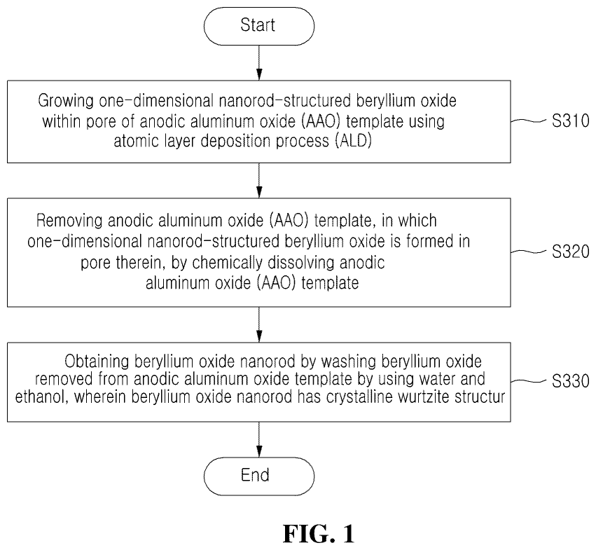

FIG. 1 is a flowchart illustrating a method for manufacturing a high aspect ratio beryllium oxide nanorod array according to an embodiment of the disclosure.

Referring to FIG. 1, a method for manufacturing a high aspect ratio beryllium oxide nanorod according to an embodiment of the disclosure includes: (S100) growing one-dimensional nanorod-structured beryllium oxide within a pore of a anodic aluminum oxide (AAO) template using an atomic layer deposition (ALD) process; (S200) removing the anodic aluminum oxide (AAO) template, in which the one-dimensional nanorod-structured beryllium oxide is formed in the pore therein, by chemically dissolving the anodic aluminum oxide (AAO) template; and (S300) obtaining a beryllium oxide nanorod by washing the beryllium oxide removed from the anodic aluminum oxide template by using water and ethanol, wherein the beryllium oxide nanorod has a crystalline wurtzite structure.

The first step may include growing one-dimensional nanorod-structured beryllium oxide within a pore of a anodic aluminum oxide (AAO) template using an atomic layer deposition (ALD) process. (S100)

A anodic aluminum oxide (AAO) template is used as a framework for creating nanostructures such as nanotubes and nanowires, and the AAO template itself may also be utilized as a nanomask. At this time, the AAO template may be used to create an aluminum substrate in which regularly arranged nanometer-sized pores are formed on the oxidized aluminum surface when anodized. At this time, the spacing between these pores is tens to hundreds of nanometers, and the size, spacing, and depth of the pores may be varied by varying the anodization conditions (anodization voltage, acid solution type and concentration, temperature, etc.).

Previous research on beryllium oxide manufacturing has been limited to the synthesis of bulk or film-type beryllium oxide, and conventional nanorod synthesis methods, such as CVD, sputtering, and evaporator methods, have been inapplicable due to the toxicity of beryllium itself.

Therefore, the disclosure utilizes an AAO template that is not damaged during the deposition process and facilitates easy mold removal through a chemical dissolution process.

At this time, the diameter of a pore of the anodic aluminum oxide (AAO) template used in the disclosure is characterized by a range of 10 nm to 400 nm, wherein if the pore diameter is less than 10 nm, low pore uniformity may be a problem, and if it exceeds 400 nm, low mechanical robustness of the template may be a problem; thus, the diameter of the pore of the anodic aluminum oxide (AAO) template may be 10 nm to 400 nm.

At this time, the atomic layer deposition (ALD) process using the anodic aluminum oxide (AAO) template is characterized by forming beryllium oxide by reacting beryllium diethyl (Be(C₂H₅)₂) as a beryllium precursor with oxygen plasma.

The sequential reaction of beryllium diethyl (Be(C₂H₅)₂) as a beryllium precursor with oxygen plasma allows for nanoscale control, and the ALD process offers the advantages of excellent uniformity and conformal one-dimensional structure.

Furthermore, the atomic layer deposition (ALD) process may manufacture a nanorod by performing a deposition process in the ALD process, the beryllium precursor injection time for one cycle may be set to 5 seconds or longer, and the purge time after the reaction of the beryllium precursor may be set to 5 seconds or longer.

The reason the beryllium precursor injection time for one cycle of the ALD process is set to 5 seconds or longer is to effectively inject the Be precursor into high aspect ratio pores, and the reason the purge time after the reaction of the beryllium precursor is set to 5 seconds or longer is to ensure sufficient removal of reaction byproducts from the AAO structure.

The second step may include removing the anodic aluminum oxide (AAO) template, in which the one-dimensional nanorod-structured beryllium oxide is formed in the pore therein, by chemically dissolving the anodic aluminum oxide (AAO) template. (S200)

Within the anodic aluminum oxide (AAO) template, a one-dimensional nanorod-structured beryllium oxide may be formed, and to facilitate the removal of the anodic aluminum oxide, a chemical dissolution process may be performed.

At this time, the chemical dissolution may be dissolving by introducing the 1 M to 3 M sodium hydroxide aqueous solution to dissolve the anodic aluminum oxide (AAO) template, in which the one-dimensional nanorod-structured beryllium oxide is formed within the internal pores.

At this time, between the depositing of the one-dimensional nanorod-structured beryllium oxide and the removing of the anodic aluminum oxide (AAO) template,

an additional step may be included: physically removing the beryllium oxide thin film deposited on the aluminum oxide (AAO) template using sandpaper to remove the beryllium oxide bridging layer, thereby obtaining the individually separated nanorods.

At this time, a film having good adhesiveness may be deposited on a anodic aluminum oxide (AAO) template on which beryllium oxide in a nanorod structure is formed, and the reason for depositing the film having good adhesiveness on a anodic aluminum oxide (AAO) template on which beryllium oxide in a nanorod structure is to fix the beryllium oxide nanorod to the film or silver paste.

Additionally, the method may further include: prior to the growing of the one-dimensional nanorod-structured beryllium oxide, depositing a metal thin film on the aluminum oxide (AAO) template; after the growing of the one-dimensional nanorod-structured beryllium oxide, chemically etching the metal thin film to chemically remove the beryllium oxide thin film deposited on the aluminum oxide (AAO) template.

At this time, the metal thin film may be formed as a 5 nm to 10 nm thick silver thin film by performing an evaporation or sputtering process.

At this time, by depositing the 5 nm to 10 nm thin metal thin film, the deposited beryllium oxide thin film may be chemically removed without blocking the pores of the AAO template during ALD process

This method of chemically removing the beryllium oxide thin film deposited on the aluminum oxide (AAO) template using the metal thin film can particularly prevent connection between beryllium oxide nanorods through the underlying film.

At this time, by fixing the beryllium oxide nanorod (e.g., using a film or silver paste), individual, a uniformly arranged beryllium oxide nanorod may be obtained after the anodic aluminum oxide (AAO) template is removed.

Without this fixation process, it is difficult to synthesize a nanorod array, as the nanorod may disperse in the solution after the anodic aluminum oxide (AAO) template is removed.

The reason for physically removing the beryllium oxide layer deposited on the surface of the anodic aluminum oxide (AAO) template using sandpaper is to prevent interconnection between nanorods.

The third step may include obtaining a beryllium oxide nanorod by washing the beryllium oxide removed from the anodic aluminum oxide template by using water and ethanol. (S300)

The beryllium oxide removed from the oxide template may be washed with water and ethanol to obtain a beryllium oxide nanorod free of impurities.

At this time, the beryllium oxide nanorod manufactured using the method for manufacturing a high aspect ratio beryllium oxide nanorod of the disclosure is a material with a high aspect ratio, and the beryllium oxide nanorod may have a width of 10 nm to 400 nm and a length of 10 μm to 100 μm.

The width and length of the nanorod may be determined by the depth and the diameter of the pore of the anodic aluminum oxide template.

A beryllium oxide nanorod according to another embodiment of the disclosure will be described.

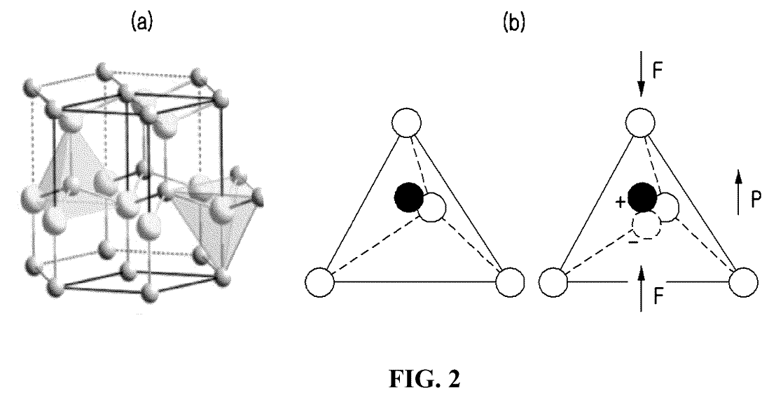

Hereinafter, with reference to FIG. 2, a beryllium oxide nanorod according to an embodiment of the disclosure will be described.

The beryllium oxide nanorod of the disclosure may have a width of 10 nm to 400 nm and a length of 10 μm to 100 μm. The nanorod has a width of 10 nm to 400 nm and a length of 10 μm to 100 μm because it can achieve high width and length uniformity within these ranges. The width and length of this nanorod may be freely controlled by templates during the manufacturing process.

At this time, the beryllium oxide nanorod may have an aspect ratio of 50 or greater, preferably 100 or greater, or an aspect ratio of 100 or greater to 1,000 or less. That is, the disclosure may induce larger deformations under a given external force through a nanorod with a controlled high aspect ratio, and may be used as a high-sensitivity, high-energy piezoelectric element. At this time, the beryllium oxide is characterized by a crystalline wurtzite structure.

At this time, the crystalline wurtzite structure of the beryllium oxide, as shown in FIG. 2, is characterized by a non-centrally symmetric tetrahedral structure, with a central axis that is not centered and lacks symmetry.

This asymmetric structure allows for piezoelectric properties and the generation of electrical potential in response to mechanical stress.

Specifically, the nanorod has a wurtzite crystal structure and, due to the lack of central symmetry, exhibits polarity along the c-axis ([0001]), resulting in piezoelectric/pyroelectric properties.

The principle of potential generation in materials exhibiting the piezoelectric properties is as follows.

When an external force is applied to a piezoelectric element, dielectric polarization may occur. When an external stress is applied to a piezoelectric BeO, the relative displacement between Be²⁺ and O²⁻ ions in its wurtzite lattice induces a dielectric polarization, resulting in a net dipole moment. When mechanical stress is applied, the crystal lattice becomes distorted, altering the ion arrangement and generating an electric potential throughout the material.

Furthermore, to exhibit piezoelectric properties, a piezoelectric material must be a dielectric and, generally, exhibit crystalline properties.

Here, the piezoelectric material is characterized by generating a charge on its surface and an electric field internally when subjected to pressure, wherein piezoelectric properties are limited to asymmetrical crystals without a central point of symmetry. In the absence of an external force, a central point of symmetry exists for the distribution of negative and positive charges. However, when an external force is applied, the central point of symmetry in the charge distribution disappears, and the center of charge shifts slightly, potentially generating electric polarization.

Therefore, the beryllium oxide nanorod of the disclosure exhibits a large aspect ratio, allowing for large deformation with less applied force compared to thin-film forms, and this allows for high sensitivity and applicability to high-energy piezoelectric devices.

In an embodiment, the nanorod (or an array thereof) exhibits a longitudinal piezoelectric coefficient (d₃₃) of 10 pm/V or greater, preferably 15 pm/V or greater, as measured (analyzed) by Piezoelectric Force Microscopy (PFM).

The beryllium oxide nanorod of the disclosure may be manufactured by performing the method for manufacturing a high aspect ratio beryllium oxide nanorod described above. However, this is not limited thereto.

A piezoelectric element according to another embodiment of the disclosure will now be described.

A piezoelectric element according to an embodiment of the disclosure is characterized by including a beryllium oxide nanorod.

In an embodiment of the disclosure, the piezoelectric element may include a first electrode, a second electrode, and a piezoelectric layer disposed between the first and second electrodes, wherein the piezoelectric layer includes the beryllium oxide nanorod.

In an embodiment, the piezoelectric layer includes an elastic matrix and a high aspect ratio beryllium oxide nanorod array dispersed in the elastic matrix, which serves as a mechanical or electrical medium for the piezoelectric element. The elastic layer may be disposed between the first electrode and the piezoelectric layer, and may specifically include, but is not limited to, PDMS in which the beryllium oxide nanorods may be embedded or integrated.

Hereinafter, the disclosure will be described in more detail through a manufacturing example and an experimental example. These manufacturing and experimental examples are solely intended to illustrate the disclosure, and the scope of the disclosure is not limited by these manufacturing and experimental examples.

### Manufacturing Example: Method for Manufacturing High Aspect Ratio Beryllium Oxide Nanorod

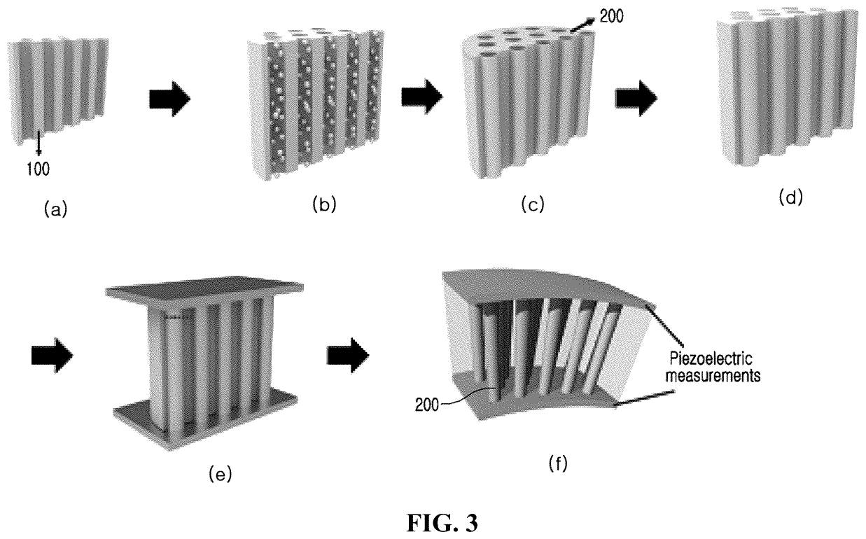

Referring to FIG. 3, the method for manufacturing a high aspect ratio beryllium oxide nanorod will be described.

### 1) Manufacturing an AAO Template With a Pore Diameter of 200 Nm

This manufacturing example used a commercially available AAO template, and the pore width and thickness may be controlled through the applied voltage, electrolyte type, and process time during AAO template synthesis.

At this time, the AAO template used in this manufacturing example has a pore diameter of 200 nm.

### 2) Beryllium Oxide Deposition Using Atomic Layer Deposition (ALD)

The AAO template was placed in an atomic layer deposition (ALD) device, and the beryllium oxide deposition process was performed with the Be precursor injection time set to at least 5 seconds per cycle and the post-reaction purge time set to 60 seconds. ((b) of FIG. 3)

### 3) Manufacturing a High Aspect Ratio Beryllium Oxide Nanorod

(c) of FIG. 3 is a schematic diagram illustrating a process of beryllium oxide deposition using an atomic layer deposition process.

At this time, the deposition may be observed from the pore walls of the AAO template.

(d) of FIG. 3 shows the AAO template after the beryllium oxide film deposited on the surface has been physically or chemically removed.

(e) of FIG. 3 shows the beryllium oxide nanorod connected to an electrode through metal deposition or Ag paste attachment.

(f) of FIG. 3 shows a piezoelectric element in which the AAO template was chemically removed using an aqueous sodium hydroxide solution and the interior was filled with a non-conductive polymer.

### Experimental Example 1: Manufacturing Verification Experiment for High Aspect Ratio Beryllium Oxide Nanorod

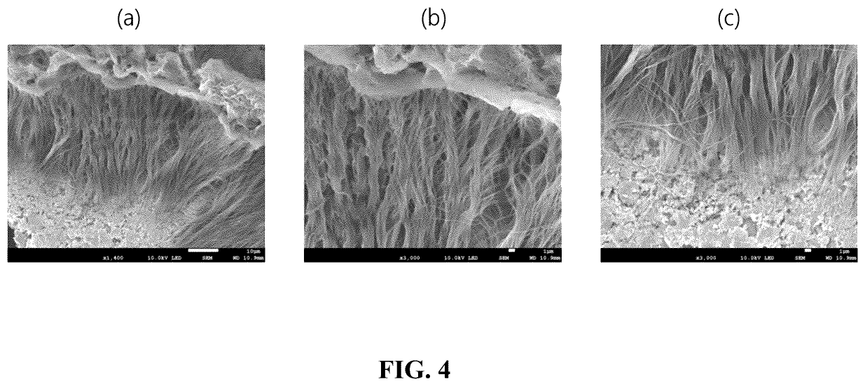

Referring to FIGS. 4 to 13, the manufacturing of a high aspect ratio beryllium oxide nanorod will be described.

FIG. 4 is a SEM image showing the top and bottom of a high aspect ratio beryllium oxide nanorod array.

Referring to FIG. 4, it can be confirmed that high aspect ratio beryllium oxide nanorods are uniformly arranged and connected to the silver paste.

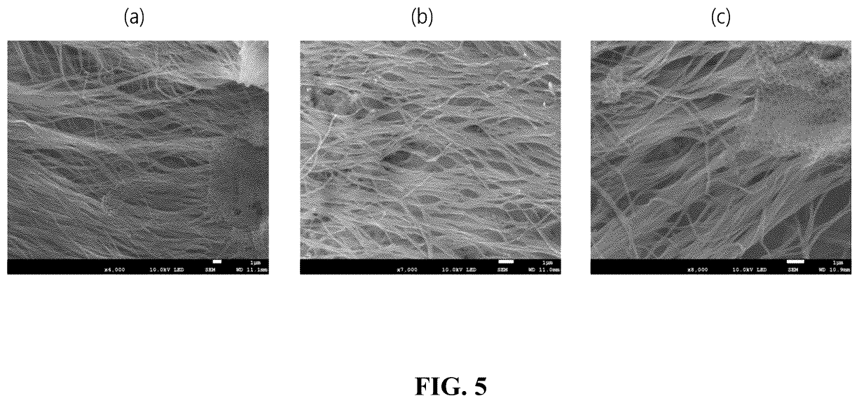

FIG. 5 is a SEM image of a high aspect ratio beryllium oxide nanorod array.

Referring to FIG. 5, it can be confirmed that high aspect ratio beryllium oxide nanorods are synthesized with a uniform width.

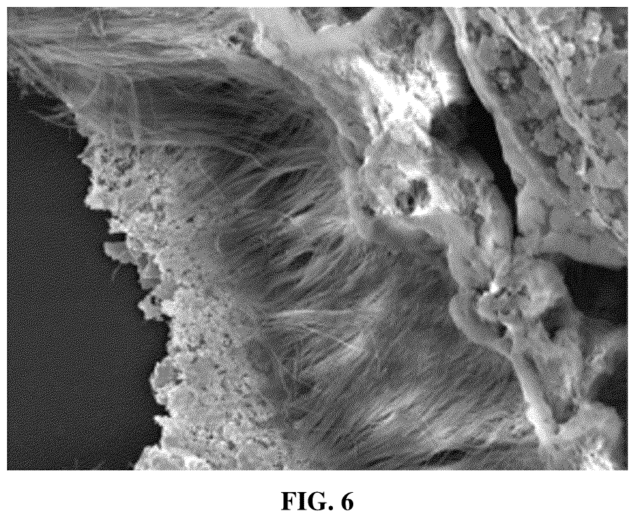

FIG. 6 is a SEM image showing a high aspect ratio beryllium oxide nanorod array.

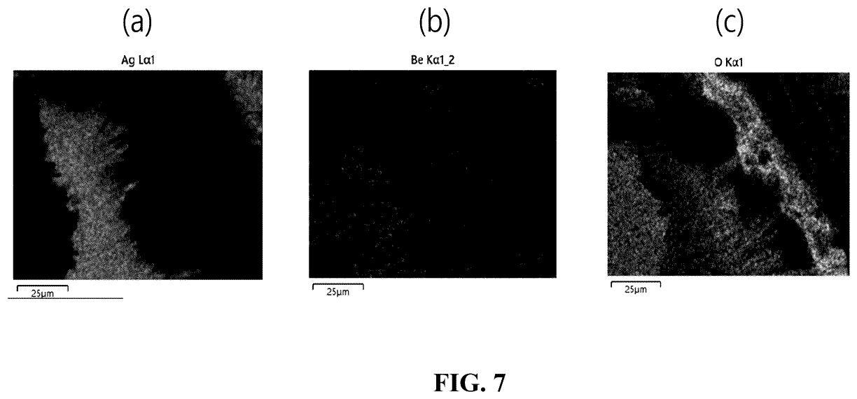

FIG. 7 is an energy-dispersive spectroscopy (SEM-EDS) elemental mapping image illustrating the results of component analysis of a high aspect ratio beryllium oxide nanorod array.

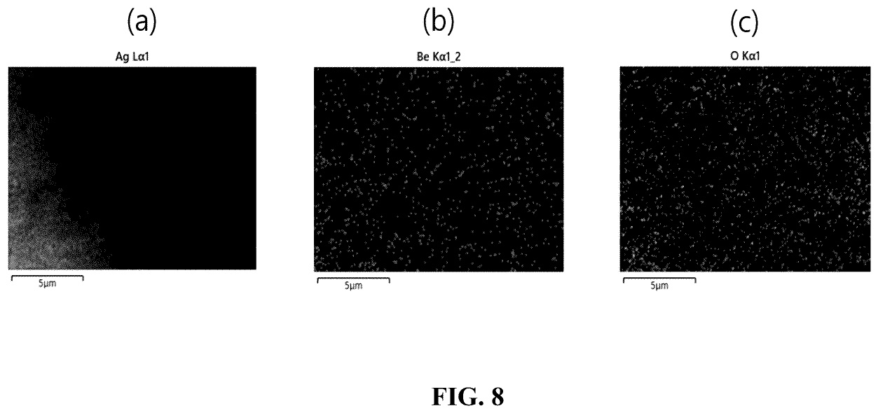

FIG. 8 is an energy-dispersive spectroscopy (SEM-EDS) elemental mapping image illustrating the results of component analysis of a high aspect ratio beryllium oxide nanorod array.

Referring to FIGS. 6 to 8, the synthesis of an array of a beryllium oxide nanorod can be confirmed.

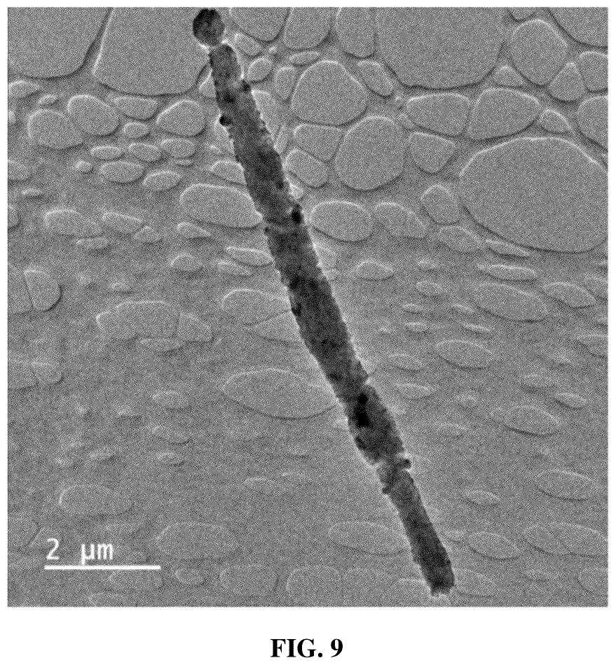

FIG. 9 is a TEM image of a high aspect ratio beryllium oxide nanorod.

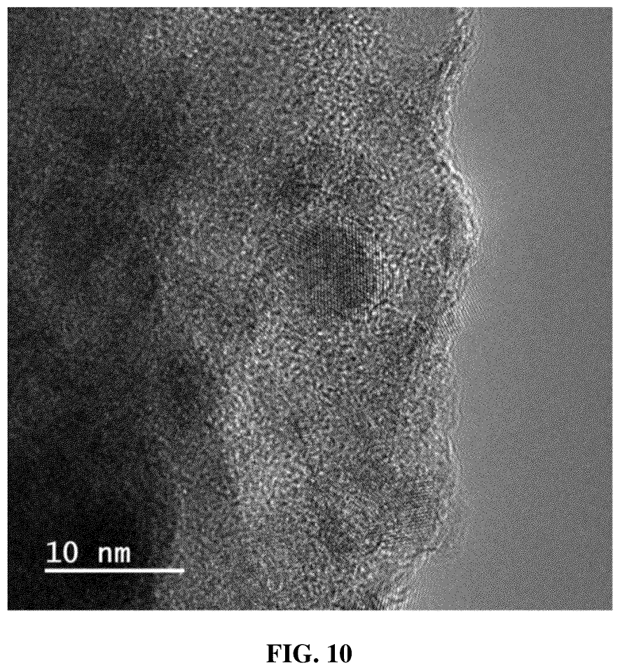

FIG. 10 is a TEM image of a high aspect ratio beryllium oxide nanorod.

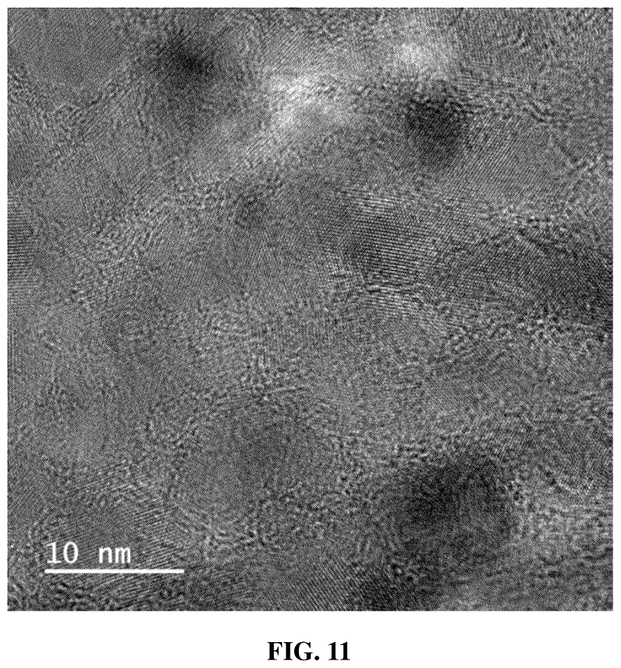

FIG. 11 is a TEM image of a high aspect ratio beryllium oxide nanorod.

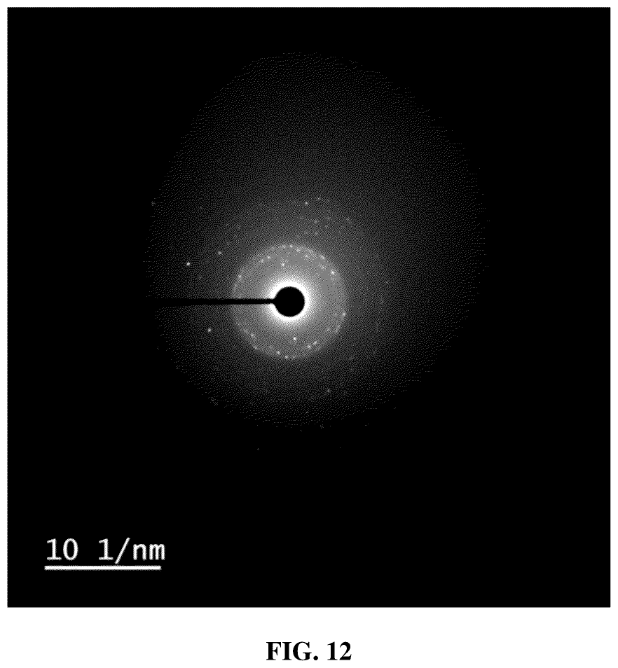

FIG. 12 is a SAD diffraction pattern of a high aspect ratio beryllium oxide nanorod.

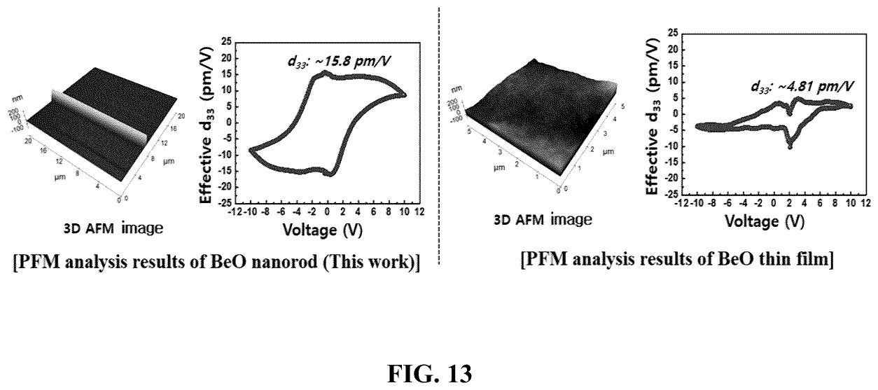

FIG. 13 is a diagram showing the piezoelectric properties of a high aspect ratio beryllium oxide nanorod.

Referring to FIGS. 9 to 13, it is possible to confirm the synthesis of a beryllium oxide nanorod and that beryllium oxide is a crystalline material.

Experimental example 2: Experimental Verification of Piezoelectric Properties and Piezoelectric Element Performance of High Aspect Ratio Beryllium Oxide Nanorod

FIG. 13 is a diagram showing the piezoelectric properties of a high aspect ratio beryllium oxide nanorod.

FIG. 13 shows 3D AFM images of a beryllium oxide nanorod and a beryllium oxide thin film, as well as voltage-displacement hysteresis curves obtained through piezoelectric force microscopy (PFM) measurements.

The PFM analysis results show that the high aspect ratio beryllium oxide nanorod of the disclosure has a longitudinal piezoelectric coefficient (d₃₃) of up to 15.8 pm/V, which is significantly higher than the piezoelectric coefficient of 4.81 pm/V of a BeO thin film measured as a comparison.

This is due to the fact that the nanorod of the disclosure has a predominantly (101) or (100) crystal orientation along the c-axis ([0001]), whereas the beryllium oxide thin film primarily has a (002) crystal orientation.

Furthermore, a piezoelectric element including a piezoelectric layer composed of the beryllium oxide nanorods of the disclosure and PDMS between electrodes was manufactured. The piezoelectric element was manufactured using the following method.

First, the top of the AAO template, on which beryllium oxide was deposited, was connected to the bottom electrode (e.g., nickel foil) using silver paste. The AAO template was then removed using a chemical dissolution method, and rinsed/washed several times with water and ethanol. Thereafter, the solvent was removed using an 80° C. oven under vacuum.

Next, the PDMS polymer precursor, base, and curing agent were mixed at a weight ratio of 10:1, and the PDMS precursor solution was spin-coated to form a thin, uniform layer on the high aspect ratio beryllium oxide nanorod, followed by curing in an 80° C. oven.

Then, the top electrode (e.g., nickel foil) was placed on top of the lower electrode/high aspect ratio beryllium oxide/PDMS layer, and then the entire structure was coated with the PDMS precursor solution, and cured for encapsulation.

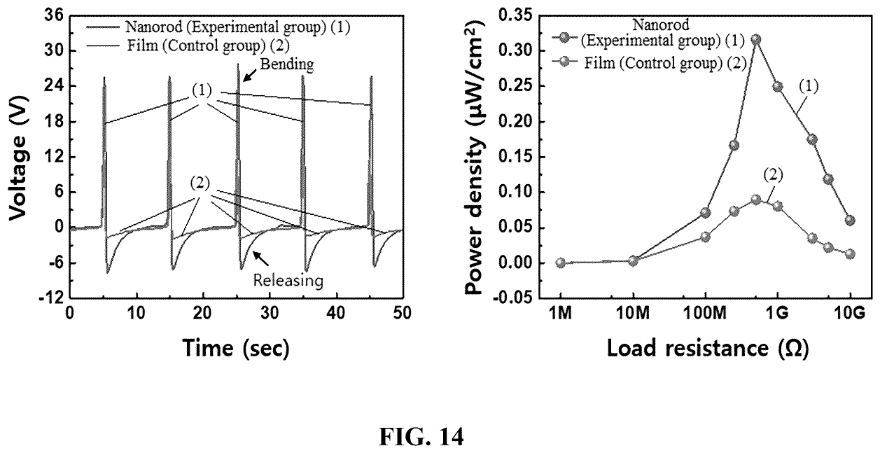

FIG. 14 is a diagram showing the improved performance of piezoelectric device based on high aspect ratio beryllium oxide nanorod array.

As a result, it can be confirmed that when a high aspect ratio beryllium oxide nanorod array is introduced into a piezoelectric element as shown in FIG. 14, it exhibits higher output voltage and power compared to a beryllium oxide film that is a control group.

The description of the disclosure is for illustrative purposes, and those skilled in the art will understand that it can be easily modified into other specific forms without changing the technical idea or essential features of the disclosure. Therefore, the embodiments described above should be understood as being exemplary in all respects and not limiting. For example, each component described as a single type may be implemented in a distributed manner, and likewise, components described as distributed may be implemented in a combined form.

The scope of the disclosure is indicated by the following claims, and all changes or modifications derived from the meaning and scope of the claims and their equivalent concepts should be interpreted as being included in the scope of the disclosure.

### EXPLANATION OF REFERENCE NUMERALS

100: anodic aluminum oxide (AAO) template
200: high aspect ratio beryllium oxide nanorod

What is claimed is:

1. A high aspect ratio beryllium oxide nanorod, comprising:
a crystalline wurtzite structure, with a width in a range of 10 nm to 400 nm and a length in a range of 10 μm to 100 μm.

2. The high aspect ratio beryllium oxide nanorod of claim 1, wherein the crystalline wurtzite structure is a non-centrosymmetric tetrahedral coordination structure, with a central axis not in a center and an asymmetric structure.

3. The high aspect ratio beryllium oxide nanorod of claim 1, wherein a longitudinal piezoelectric coefficient is greater than or equal to 10 pm/V.

4. A method for manufacturing a high aspect ratio beryllium oxide nanorod, the method comprising:
growing one-dimensional nanorod-structured beryllium oxide within a pore of an anodic aluminum oxide (AAO) template using an atomic layer deposition (ALD) process;
removing the AAO template, in which the one-dimensional nanorod-structured beryllium oxide is formed in the pore therein, by chemically dissolving the AAO template; and
obtaining the high aspect ratio beryllium oxide nanorod by washing the one-dimensional nanorod-structured beryllium oxide removed from the AAO template by using water and ethanol,
wherein the high aspect ratio beryllium oxide nanorod has a crystalline wurtzite structure.

5. The method of claim 4, wherein in the growing the one-dimensional nanorod-structured beryllium oxide, a diameter of the pore of the AAO template is in a range of 10 nm to 400 nm.

6. The method of claim 4, wherein in the growing the one-dimensional nanorod-structured beryllium oxide, the ALD process forms the one-dimensional nanorod-structured beryllium oxide by reacting beryllium diethyl (Be(C₂H₅)₂) as a beryllium precursor with oxygen plasma.

7. The method of claim 6, wherein in the ALD process, one cycle is set to have a beryllium precursor injection time of at least 5 seconds and a purge time of at least 60 seconds after a reaction of the beryllium precursor and the oxygen plasma.

8. The method of claim 4, wherein in the removing the AAO template, the chemically dissolving is performed by introducing, into a sodium hydroxide aqueous solution, the AAO template in which the one-dimensional nanorod-structured beryllium oxide is formed in the pore therein.

9. The method of claim 4, wherein in the obtaining the high aspect ratio beryllium oxide nanorod, the high aspect ratio beryllium oxide nanorod has a width in a range of 10 nm to 400 nm and a length in a range of 10 μm to 100 μm.

10. The method of claim 4, further comprising, between the growing the one-dimensional nanorod-structured beryllium oxide and the removing the AAO template, physically removing a beryllium oxide thin film deposited on the AAO template by using sandpaper.

11. The method of claim 4, further comprising:
before the growing the one-dimensional nanorod-structured beryllium oxide, depositing a metal thin film on the AAO template; and
after the growing the one-dimensional nanorod-structured beryllium oxide, chemically etching the metal thin film to chemically remove a beryllium oxide film deposited on the AAO template.

12. A beryllium oxide nanorod characterized by being manufactured by performing the method for manufacturing the high aspect ratio beryllium oxide nanorod of claim 4.

13. A piezoelectric element, comprising:
a first electrode;
a second electrode; and
a piezoelectric layer disposed between the first electrode and the second electrode,
wherein the piezoelectric layer comprises the high aspect ratio beryllium oxide nanorod of claim 1.

14. The piezoelectric element of claim 13, wherein the piezoelectric layer includes an elastic matrix and a high aspect ratio beryllium oxide nanorod array dispersed in the elastic matrix.
